(19) United States
(12) Patent Application Publication
(10) Pub. No.: US 2026/0165179 A1
(43) Pub. Date: Jun. 11, 2026

(54) SEMICONDUCTOR DEVICE

(71) Applicant: FUJI ELECTRIC CO., LTD., Kawasaki-shi, Kanagawa (JP)

(72) Inventors: Yuta TAMAI, Matsumoto-city (JP); Motohito HORI, Matsumoto-city (JP); Mai SAITO, Matsumoto-city (JP)

(73) Assignee: FUJI ELECTRIC CO., LTD., Kawasaki-shi (JP)

(21) Appl. No.: 19/463,630

(22) Filed: Jan. 29, 2026

Related U.S. Application Data
(63) Continuation of application No. PCT/JP2025/000040, filed on Jan. 6, 2025.

(30) Foreign Application Priority Data
Mar. 15, 2024 (JP) 2024-041066

(51) Int. Cl. H10W 72/30; H10W 40/20; H10W 90/00

(52) U.S. Cl. CPC H10W 72/324; H10W 40/233; H10W 72/334; H10W 72/365; H10W 90/736

(57) ABSTRACT

A semiconductor device, including: a semiconductor module having a lower surface; a cooling module including a placement surface on which the semiconductor module is placed, the placement surface being in contact with the lower surface of the semiconductor module; and a bonding member provided between the placement surface of the cooling module and the lower surface of the semiconductor module. The bonding member includes: an adhesive part that bonds the lower surface of the semiconductor module and the placement surface of the cooling module, and a spacer part that is provided at a periphery of the adhesive part, bonds the lower surface of the semiconductor module and the placement surface of the cooling module, and contains a first filler.

### CROSS-REFERENCE TO RELATED APPLICATION(S)

This application is a continuation application of International Application PCT/JP2025/000040 filed on Jan. 6, 2025, which designated the U.S., and claims priority to Japanese Patent Application 2024-041066, filed on Mar. 15, 2024, the entire contents of which are incorporated herein by reference.

### BACKGROUND OF THE INVENTION

### 1. Field of the Invention

The embodiments discussed herein relate to a semiconductor device.

### 2. Background of the Related Art

In a semiconductor device, a substrate on which electronic components are mounted is encapsulated with an encapsulating member (for example, Japanese Laid-open Patent Publication No. 2014-232828). In another semiconductor device, a semiconductor module is disposed via a bonding member on a cooling module to dissipate heat (see, for example, Japanese Laid-open Patent Publication No. 2023-103785). As one example, the bonding member contains an organic resin and a thermally conductive material as main components (see, for example, Japanese Laid-open Patent Publication No. 2018-046166). When the bonding member contains a thermally conductive filler, the thermal conductivity is improved (see, for example, Japanese Laid-open Patent Publication No. 2009-252886). A certain height is maintained for the bonding member between the semiconductor module and the cooling module (see, for example, International Publication Pamphlet No. WO 2017/038460, Japanese Laid-open Patent Publication No. 10-050928,Japanese Laid-open Patent Publication No. 2017-199829,and Japanese Laid-open Patent Publication No. 2012-028433).

### SUMMARY OF THE INVENTION

According to an aspect of the present disclosure, there is provided a semiconductor device, including: a semiconductor module having a lower surface; a cooling module including a placement surface on which the semiconductor module is placed, the placement surface being in contact with the lower surface of the semiconductor module; and a bonding member provided between the placement surface of the cooling module and the lower surface of the semiconductor module, the bonding member including: an adhesive part that bonds the lower surface of the semiconductor module and the placement surface of the cooling module, and a spacer part that is provided at a periphery of the adhesive part, bonds the lower surface of the semiconductor module and the placement surface of the cooling module, and contains a first filler.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a cross-sectional view of the semiconductor device according to the first embodiment;

FIG. 3 is a rear view of the semiconductor module included in the semiconductor device according to the first embodiment;

FIG. 4 is a rear view of a semiconductor module to which a bonding member has been applied and which is included in the semiconductor device according to the first embodiment;

FIG. 5 is an enlarged cross-sectional view of the semiconductor device according to the first embodiment;

FIG. 6 is a cross-sectional view of a semiconductor device according to a comparative example;

FIG. 7 is an enlarged cross-sectional view of the semiconductor device according to the first embodiment (modification 1-1);

FIG. 8 is a rear view of a semiconductor module to which a bonding member has been applied and which is included in the semiconductor device according to the first embodiment (modification 1-2);

FIG. 9 is a plan view of the semiconductor device according to the first embodiment (modification 1-3);

FIG. 10 is a cross-sectional view of the semiconductor device according to the first embodiment (modification 1-3);

FIG. 11 is a cross-sectional view of a semiconductor device according to a second embodiment;

FIG. 12 is a rear view of a semiconductor module to which a bonding member has been applied and which is included in the semiconductor device according to the second embodiment;

FIG. 13 is a cross-sectional view of a semiconductor device according to a third embodiment;

FIG. 14 is a plan view of a cooling module to which a bonding member is applied and which is included in the semiconductor device according to the third embodiment;

FIG. 15 is a plan view of a cooling module to which a bonding member has been applied and which is included in the semiconductor device according to the third embodiment (modification 3-1);

FIG. 16 is a plan view of a cooling module to which a bonding member has been applied and which is included in the semiconductor device according to the third embodiment (modification 3-2);

FIG. 17 is a plan view of a cooling module to which a bonding member has been applied and which is included in the semiconductor device according to the third embodiment (modification 3-3);

FIG. 18 is a cross-sectional view of a semiconductor device according to a fourth embodiment; and

FIG. 19 is a cross-sectional view of a semiconductor device according to a fifth embodiment.

### DETAILED DESCRIPTION OF THE INVENTION

Hereinafter, several embodiments will be described with reference to the drawings. In the following description, the expressions “front surface” and “upper surface” refer to an X-Y plane that faces upward (in the +Z direction) for the semiconductor device in the drawings. In the same way, the expression “up” indicates an upward direction (+Z direction) for the semiconductor device in the drawings. The expressions “rear surface” and “lower surface” represent an X-Y plane that faces downward (in the −Z direction) for the semiconductor device in the drawings. In the same way, the expression “down” indicates a downward direction (−Z direction) for the semiconductor device in the drawings. The same directions as given here are indicated as needed in all drawings. The expressions “higher” and “above” indicate upper-side positions (in the +Z direction) for the semiconductor device in the drawings. In the same way, “lower” and “below” represent lower-side positions (in the −Z direction) for the semiconductor device in the drawings. The expressions “front surface”, “upper surface”, “upper” and “rear surface”, “lower surface”, “lower” and “side surface” are merely convenient expressions used to specify relative positional relationships, and do not limit the technical scope of the present embodiments. For example, “up” and “down” do not necessarily refer to the vertical direction with respect to the ground. That is, the “up” and “down” directions are not limited to the direction of gravity. Also in the following description, the expression “main component” refers to a component contained in an amount of 80% or more. The expression “substantially the same” may be within a range of ±10%. Other expressions such as “perpendicular”, “orthogonal”, and “parallel” may also be within a range of ±10°.

### First Embodiment

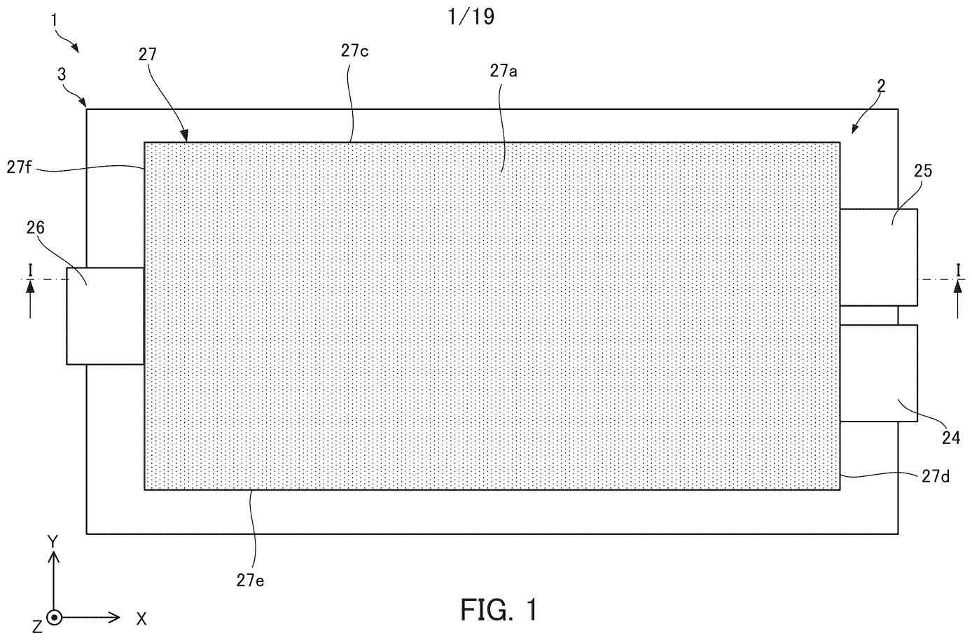

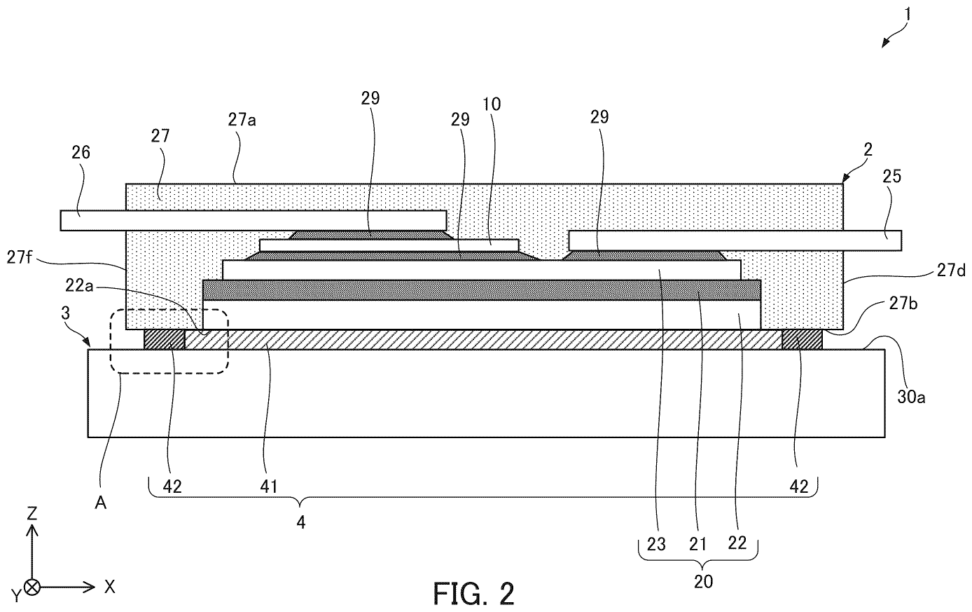

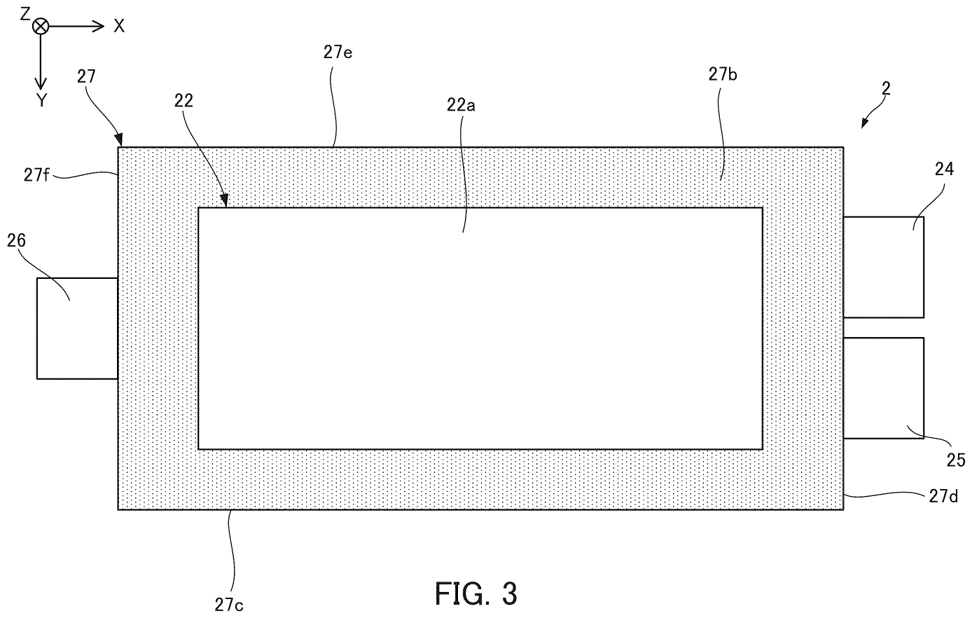

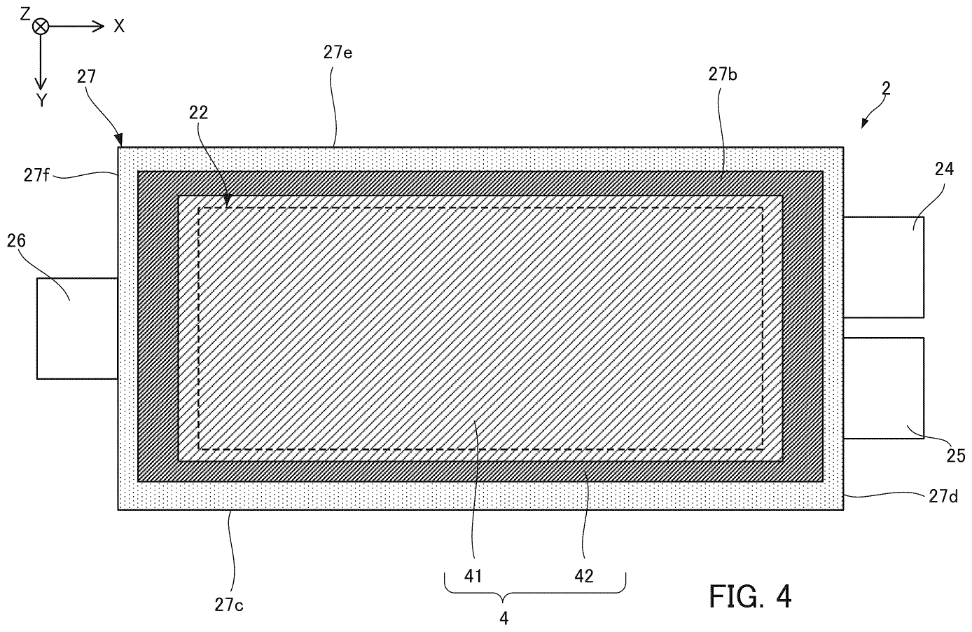

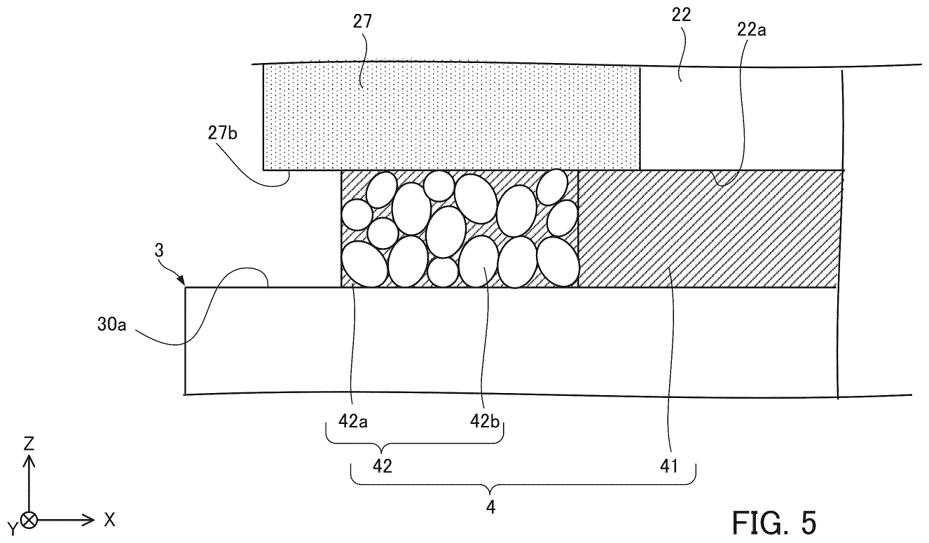

A semiconductor device 1 according to a first embodiment will now be described with reference to FIGS. 1 to 5. FIG. 1 is a plan view of a semiconductor device according to the first embodiment, and FIG. 2 is a cross-sectional view of the semiconductor device according to the first embodiment. FIG. 3 is a rear view of the semiconductor module included in the semiconductor device according to the first embodiment, and FIG. 4 is a rear view of a semiconductor module to which a bonding member has been applied and which is included in the semiconductor device according to the first embodiment. FIG. 5 is an enlarged cross-sectional view of the semiconductor device according to the first embodiment. FIG. 2 is a cross-sectional view taken along a chain line I-I in FIG. 1. In FIG. 4, the range of the metal plate 22 is indicated by a broken line. FIG. 5 is an enlarged cross-sectional view of a region A in FIG. 2.

The semiconductor device 1 includes a semiconductor module 2, a cooling module 3, and a bonding member 4 that fixes the cooling module 3 to the semiconductor module 2. Note that the semiconductor device 1 may also include other components as needed in addition to these components.

The semiconductor module 2 includes a semiconductor chip 10, an insulated circuit board 20, external terminals 24, 25, and 26, and an encapsulating member 27 that encapsulates these components. However, the outer ends of the external terminals 24, 25, and 26 are exposed from the encapsulating member 27.

The semiconductor chip 10 may be a power metal-oxide-semiconductor field-effect transistor (MOSFET) that has silicon carbide as a main component. In the power MOSFET, the body diode may function as a freewheeling diode (FWD). The semiconductor chip 10 includes an input electrode (drain electrode) as a main electrode on the rear surface, and an output electrode (source electrode) as a main electrode and a control electrode (gate electrode) on the front surface. Note that the control electrode may be provided at the center of one edge of the front surface of the semiconductor chip 10 or at a position shifted from the center along the edge.

The semiconductor chip 10 may be semiconductor chips that have silicon as a main component and include a pair of a switching element and a diode element. In more detail, one semiconductor chip may be a switching element, and the other semiconductor chip may be a diode element. The switching element is a power MOSFET or an insulated gate bipolar transistor (IGBT), for example. A semiconductor chip including a switching element includes, for example, an input electrode (a drain electrode in a power MOSFET and a collector electrode in an IGBT) as a main electrode on a rear surface and a gate electrode as a control electrode and an output electrode (a source electrode in a power MOSFET and an emitter electrode in an IGBT) as a main electrode on a front surface. As examples of the diode element, a Schottky barrier diode (SBD) or a P-intrinsic-N (PiN) diode is used as an FWD. A semiconductor chip including a diode element includes an output electrode (cathode electrode) as a main electrode on the rear surface and an input electrode (anode electrode) as a main electrode on the front surface.

Alternatively, the semiconductor chip 10 may include a switching element that has silicon as a main component. The switching element may be an IGBT or a reverse-conducting (RC)-IGBT, for example. An RC-IGBT is a semiconductor element in which an IGBT and an FWD are configured in anti-parallel in a single chip. Such a semiconductor chip 10 includes an input electrode (collector electrode) as a main electrode on the rear surface, and an output electrode (emitter electrode) as a main electrode and a control electrode (gate electrode) on the front surface. As with a power MOSFET, the control electrode may be provided at the center of one edge of the front surface of the semiconductor chip 10 or at a position shifted from the center along the edge.

The semiconductor chip 10 is bonded to a conductive circuit pattern 23 of an insulated circuit board 20 described later by a bonding member 29. The bonding member 29 may be solder. The solder is made up of a solder component. The solder component includes lead-free solder containing a predetermined alloy as a main component. The predetermined alloy contains tin. Example alloys include at least one of tin-silver alloy, tin-silver-copper alloy, tin-zinc-bismuth alloy, tin-copper alloy, tin-silver-indium-bismuth alloy, and tin-antimony alloy. The solder component may also include additives. Example additives include nickel, germanium, cobalt, and silicon. Accordingly, examples of the solder component include tin and at least one of silver, zinc, copper, bismuth, indium, and antimony. The solder component may further include at least one of nickel, germanium, cobalt, and silicon, for example.

The bonding member 29 may be sintered metal. Examples of sintered material when bonding is performed with sintered metal include powder of silver, iron, copper, aluminum, titanium, nickel, tungsten, or molybdenum. As examples, the thickness of the bonding member 29 may be 50 μm or more and 300 μm or less.

The insulated circuit board 20 includes an insulating layer 21, a metal plate 22, and a conductive circuit pattern 23. The insulating layer 21 and the metal plate 22 are rectangular in shape in plan view. Corner portions of the insulating layer 21 and the metal plate 22 may be chamfered into rounded or beveled shapes.

The insulating layer 21 is made of resin, for example. The resin may be a material that has low thermal resistance but is a favorable electrical insulator and has high heat resistance. Example resins include a thermosetting resin and a thermoplastic resin. Such resins may further contain a filler. It is possible to further reduce the thermal resistance of the insulating layer 21 by controlling the material and content of the filler in the insulating layer 21. Depending on the filler, it may be possible to make the linear expansion coefficient of the insulating layer 21 substantially equal to the linear expansion coefficients of the metal plate 22 and the conductive circuit pattern 23 described later. By reducing the difference in the linear expansion coefficients, it is possible to reduce warping of the insulated circuit board 20 due to differences in linear expansion coefficients, even when thermal changes occur. Note that when doing so, the difference in linear expansion coefficients in this case may be within an error range of 10% or higher and 30% or lower. This means that in the semiconductor device 1 including the insulated circuit board 20 in which the insulating layer 21 is made of resin, warping due to heat cycles is smaller than when the insulating layer 21 is a ceramic substrate as described later. In the first embodiment, the insulating layer 21 is made of resin.

Examples of the thermosetting resin used here include at least one of epoxy resin, cyanate resin, benzoxazine resin, unsaturated polyester resin, phenol resin, melamine resin, silicone resin, and maleimide resin. Examples of thermoplastic resin include at least one of polyimide resin, acrylic resin, and polyamide resin. The filler is made of at least one of an oxide and a nitride. Example oxides include silicon oxide and aluminum oxide. Example nitrides include silicon nitride, aluminum nitride, and boron nitride. Hexagonal boron nitride may also be used as the filler. The thickness of the insulating layer 21 depends on the rated voltage of the semiconductor device 1. That is, the thickness of the insulating layer 21 needs to be increased as the rated voltage of the semiconductor device 1 increases. On the other hand, it is also important to make the insulating layer 21 as thin as possible to reduce the thermal resistance.

The insulating layer 21 may be a ceramics substrate instead of resin. The ceramic substrate is made of ceramic with favorable thermal conductivity. As examples, the ceramic is a material containing aluminum oxide, aluminum nitride, or silicon nitride as a main component. As examples, it is possible to use a direct copper bonding (DCB) substrate or an active metal brazed (AMB) substrate as the insulated circuit board 20 with the insulating layer 21 of the configuration described above.

Note that in the first embodiment, it is assumed that the insulating layer 21 is made of resin and the difference between the linear expansion coefficient of the insulating layer 21 and the linear expansion coefficients of the metal plate 22 and the conductive circuit pattern 23 is small.

The metal plate 22 is made of a metal with superior thermal conductivity. Example materials include copper, aluminum, and an alloy containing at least one of such metals. Note that a lower surface 22a of the metal plate 22 also forms part of the lower surface of the insulated circuit board 20. The lower surface 22a of the metal plate 22 is also exposed from a lower surface 27b of the encapsulating member 27, described later. When doing so, the lower surface 22a of the metal plate 22 may protrude outward (in the −Z direction) from the lower surface 27b of the encapsulating member 27, or may be flush with the lower surface 27b of the encapsulating member 27. In the first embodiment, the lower surface 22a of the metal plate 22 is flush with the lower surface 27b of the encapsulating member 27.

The semiconductor chip 10 is disposed on the conductive circuit pattern 23. The conductive circuit pattern 23 is formed over the entire surface of the insulating layer 21 except for edge portions thereof. It is preferable for the end portions of the conductive circuit pattern 23 that face the outer periphery of the insulating layer 21 to coincide with outer peripheral end portions of the metal plate 22 in plan view. This means that in the insulated circuit board 20, stress is kept balanced between the conductive circuit pattern 23 and the metal plate 22 on the rear surface of the insulating layer 21. This further suppresses excessive warping of the insulating layer 21, for example, damage in the form of cracking.

The conductive circuit pattern 23 is made of a material having excellent electrical conductivity. Examples of such a material include copper, aluminum, and an alloy containing at least one of them. The conductive circuit pattern 23 included in the semiconductor device 1 according to the first embodiment is merely one example. The number, shape, size, and the like of the conductive circuit patterns 23 may be appropriately selected as needed.

The external terminals 24, 25, and 26 are made of a metal with superior electrical conductivity. Example materials include copper, aluminum, and an alloy containing at least one of such metals. Surfaces of the external terminals 24, 25, and 26 may be plated to improve corrosion resistance. Example plating materials include nickel, nickel-phosphorus alloy, and nickel-boron alloy. The external terminals 24, 25, and 26 correspond to a positive electrode terminal, a negative electrode terminal, and an output terminal of the semiconductor module 2, respectively. Inner end portions of the external terminals 24, 25, and 26 may be bonded by the bonding member 29 to the output electrode and the conductive circuit pattern 23 on the front surface of the semiconductor chip 10. Outer end portions of the external terminals 24, 25, and 26 extend in parallel with the front surface of the insulated circuit board 20.

The encapsulating member 27 encapsulates the front side and side portions of the insulated circuit board 20 and the entire semiconductor chip 10. The encapsulating member 27 encapsulates the external terminals 24, 25, and 26 aside from their outer end portions. The external terminals 24 and 25 and the external terminal 26 may extend from the short side surfaces 27d and 27f of the encapsulating member 27 to the outside perpendicularly to the short side surfaces 27d and 27f, respectively. In addition, the encapsulating member 27 may encapsulate other components aside from those mentioned here. Depending on the component, some components may be exposed to the outside from the encapsulating member 27.

The encapsulating member 27 may be shaped as a cuboid, for example. Edge portions of the encapsulating member 27 may be chamfered into rounded shapes. The encapsulating member 27 includes an upper surface 27a, the lower surface 27b, and a long side surface 27c, the short side surface 27d, a long side surface 27e, and a short side surface 27f that surround the four sides of the upper surface 27a and the lower surface 27b in that order. The surfaces of the encapsulating member 27 may be substantially flat.

The upper surface 27a and the lower surface 27b may be rectangular in shape in plan view and be substantially parallel to the X-Y plane. The upper surface 27a and the lower surface 27b may have the same shape and the same size. The long side surfaces 27c and 27e may be substantially parallel to the X-Z plane and connect the long sides of the upper surface 27a and the lower surface 27b, respectively. The short side surfaces 27d and 27f may be substantially parallel to the Y-Z plane and connect the short sides of the upper surface 27a and the lower surface 27b, respectively. The respective ends of the long side surface 27c, the short side surface 27d, the long side surface 27e, and the short side surface 27f are integrally connected.

The encapsulating member 27 may be a thermosetting resin containing a filler. That is, the encapsulating member 27 may have an electrically insulating filler and a resin (thermosetting resin) as a main component. In this case, the thermosetting resin is epoxy resin, phenol resin, maleimide resin, or polyester resin, for example. The filler may contain an electrically insulating ceramic with high thermal conductivity as a main component. Examples of the filler include silicon oxide, aluminum oxide, boron nitride, and aluminum nitride. The content of the filler is 50% by volume or higher and 90% by volume or lower with respect to the encapsulating member 27 as a whole.

The cooling module 3 includes, on an upper surface, a placement surface 30a on which the semiconductor module 2 is placed. The placement surface 30a is wider than the rear surface of the semiconductor module 2 and is flat. As one example, the cooling module 3 may be a heat dissipation base including heat dissipation fins or a cooling device in which a refrigerant internally circulates.

The bonding member 4 has an adhesive property and is provided between the lower surface 22a of the metal plate 22 of the semiconductor module 2 and the lower surface 27b of the encapsulating member 27, and the placement surface 30a of the cooling module 3. The bonding member 4 further includes an adhesive part 41 and a spacer part 42.

The adhesive part 41 bonds the lower surface 22a and the lower surface 27b of the semiconductor module 2 to the placement surface 30a of the cooling module 3. The adhesive part 41 is in contact with at least the entire lower surface 22a of the metal plate 22 included in the semiconductor module 2. To do so, the adhesive part 41 is rectangular in shape in plan view as with the lower surface 22a of the metal plate 22. A base material of the adhesive part 41 is an adhesive. This adhesive may be epoxy-based resin, for example. The adhesive part 41 has higher thermal conductivity than the spacer part 42.

As depicted in FIGS. 4 and 5, the spacer part 42 is provided around the outer periphery of the adhesive part 41, bonds the lower surface 27b of the semiconductor module 2 and the placement surface 30a of the cooling module 3, and contains a filler 42b (or “first filler”). A base material 42a of the spacer part 42 may be the same material as the adhesive part 41. The base material 42a is filled with the filler 42b. The spacer part 42 is formed in a continuous annular shape that contacts and surrounds the outer periphery of the adhesive part 41, and is in contact with the lower surface 27b of the encapsulating member 27 of the semiconductor module 2. In the first embodiment, the spacer part 42 is provided between the lower surface 27b of the encapsulating member 27 of the semiconductor module 2 and the placement surface 30a of the cooling module 3 while leaving the outer periphery of the lower surface 27b open. The spacer part 42 has higher adhesive strength than the adhesive part 41.

The filler 42b may be formed in the shape of spheres or scales, for example. As one example, the filler 42b may be metal particles that are electrically conductive or inorganic particles. As examples, the metal particles may be made of silver, copper, gold, nickel, chromium, aluminum, or an alloy containing at least one of these metals. Examples of the inorganic particles include a ceramic that is highly electrically insulating and highly thermally conductive. Example ceramics include at least one of aluminum oxide, aluminum nitride, silicon nitride, and boron nitride. The filler 42b contained in the spacer part 42 is not limited to containing one type of metal particles or one type of inorganic particles, and may contain various types of metal particles, various types of inorganic particles, or both metal particles and inorganic particles.

The filler 42b may be pre-mixed with the spacer part 42. Alternatively, the filler 42b may be introduced into the spacer part 42 after the bonding member 4, which does not contain the filler 42b, has been applied to either the semiconductor module 2 or the cooling module 3.

In this bonding member 4, the materials and amounts of the base material of the adhesive part 41 and the base material 42a and the filler 42b of the spacer part 42 may be selected so that the thermal conductivity of the adhesive part 41 is higher than the thermal conductivity of the spacer part 42 and the bonding strength of the spacer part 42 is higher than the bonding strength of the adhesive part 41. In this case, the base material of the adhesive part 41 and the base material 42a of the spacer part 42 may be the same or may differ.

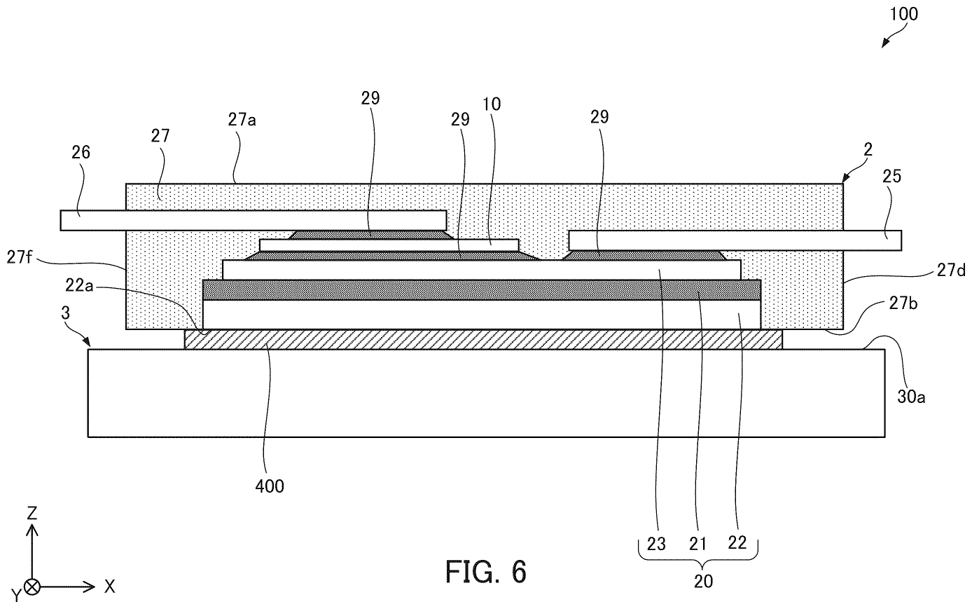

Here, a semiconductor device according to a comparative example to be compared with the semiconductor device 1 will be described with reference to FIG. 6. FIG. 6 is a cross-sectional view of a semiconductor device according to a comparative example. Note that FIG. 6 corresponds to FIG. 2 of the semiconductor device 1.

A semiconductor device 100 according to the comparative example includes the semiconductor module 2, the cooling module 3, and a bonding member 400 that bonds the semiconductor module 2 and the cooling module 3. The semiconductor module 2 and the cooling module 3 included in the semiconductor device 100 according to the comparative example have the same configurations as in the semiconductor device 1.

As with the bonding member 4, the bonding member 400 according to the comparative example is provided between the lower surfaces 22a and 27b of the semiconductor module 2 and the placement surface 30a of the cooling module 3. The range where the bonding member 400 is placed is also the same as the bonding member 4. However, unlike the bonding member 4, the bonding member 400 does not include the adhesive part 41 and the spacer part 42, and is entirely made of the same material.

As one example, thermal interface materials (hereinafter, “TIM”) may be used as the bonding member 400 of the comparative example. TIM include various materials such as thermally conductive grease, an elastomer sheet, room temperature vulcanization (RTV) rubber, gel, and a phase change material. The TIM may include an organic resin and a thermally conductive material held within the organic resin. Examples of organic resin include epoxy resin, phenol resin, and maleimide resin. As examples, the thermally conductive material is particles of a metal such as silver, copper, gold, nickel, chromium, or aluminum, particles of an alloy of such metals, or particles of a ceramic such as aluminum nitride, silicon carbide, or alumina, which have relatively high thermal conductivity.

In the semiconductor device 100, the bonding member 400 needs to achieve a certain level or higher of both heat dissipation and adhesion. To sufficiently dissipate heat, the bonding member 400 needs to have reduced thickness. To achieve reliable adhesion for the bonding member 400, the material needs to be selected with consideration to the stress generated in the bonding member 400 and the thickness needs to be increased. For this reason, the thickness of the bonding member 400 needs to be controlled so as to achieve both sufficient heat dissipation and reliability.

On the other hand, in the semiconductor device 100, when the changes in temperature occur due to heat cycles, compressive stress and tensile stress are repeatedly generated in the bonding member 400 due to the difference in linear expansion coefficients between the semiconductor module 2 and the cooling module 3. When this happens, damage such as cracking or peeling will occur in the bonding member 400, which produces gaps at the interface. This risks a drop in at least one of the heat dissipation and the adhesion of the bonding member 400. When there is a drop in heat dissipation, the semiconductor module 2 is not sufficiently cooled, resulting in increased risk of failure occurring for the semiconductor module 2. When there is a drop in adhesion, there is increased risk of delamination of the semiconductor module 2 and the cooling module 3. This results in reduced reliability for the semiconductor device 100.

On the other hand, the semiconductor device 1 includes the semiconductor module 2, which is provided with the lower surface 22a of the metal plate 22 and the lower surface 27b of the encapsulating member 27, the cooling module 3, which is provided with the placement surface 30a on which the lower surfaces 22a and 27b of the semiconductor module 2 are placed, and the bonding member 4 which exhibits adhesion and is provided between the placement surface 30a of the cooling module 3 and the lower surfaces 22a and 27b of the semiconductor module 2.

The bonding member 4 includes the adhesive part 41 and the spacer part 42. The adhesive part 41 bonds the lower surface 22a of the metal plate 22 of the semiconductor module 2 and the placement surface 30a of the cooling module 3. The spacer part 42 is provided at the outer periphery of the adhesive part 41, bonds the lower surface 27b of the encapsulating member 27 of the semiconductor module 2 and the placement surface 30a of the cooling module 3, and contains the filler 42b. That is, the spacer part 42 in the outer periphery of the bonding member 4 includes the filler 42b. This makes it possible to control and maintain the thickness of the bonding member 4 at a desired thickness using the filler 42b in the outer periphery of the bonding member 4. For this reason, it is possible to maintain the desired levels of heat dissipation and adhesion, and to achieve heat dissipation and adhesion at the same time. As one example, the thickness of the bonding member 4 may be controlled so that the bonding member 4 has the desired range of thermal conductivity and the desired range of adhesive strength. As examples, the thickness may be 50 μm or more and 300 μm or less.

The thermal conductivity of the adhesive part 41 is higher than the thermal conductivity of the spacer part 42. By including the (filler 42b included in the) spacer part 42, the bonding member 4 has uniform overall thickness and is horizontal. This means that there is no biasing in the heat dissipation by the adhesive part 41 of the bonding member 4, making it possible to uniformly cool the lower surface 22a of the metal plate 22 of the semiconductor module 2. The bonding member 4 that has uniform thickness does not become thinner at its end portions, which prevents stress from being concentrated at such parts. The adhesive strength of the spacer part 42 is also higher than the adhesive strength of the adhesive part 41. This makes it possible for the spacer part 42 to more reliably and stably bond the lower surface 27b of the encapsulating member 27 of the semiconductor module 2 and the placement surface 30a of the cooling module 3. This prevents a drop in the reliability of the semiconductor device 1.

When the thickness of the bonding member 4 is maintained as described above, the filler 42b does not need to be uniformly dispersed in the entire spacer part 42. The filler 42b may be distributed in the spacer part 42 so that the density is higher at the four corners of the spacer part 42 in plan view than at other parts. As another example, the distribution of the filler 42b in the spacer part 42 may be such that at least one of facing length-direction parts and facing width-direction parts of the spacer part 42 in plan view have a higher density than other parts.

Modifications to the first embodiment will now be described. In the following modifications, unless otherwise specified, the semiconductor module and the cooling module included in the semiconductor device according to the modifications may have the same configurations as the semiconductor module 2 and the cooling module 3 included in the semiconductor device 1 according to the first embodiment.

### Modification 1-1

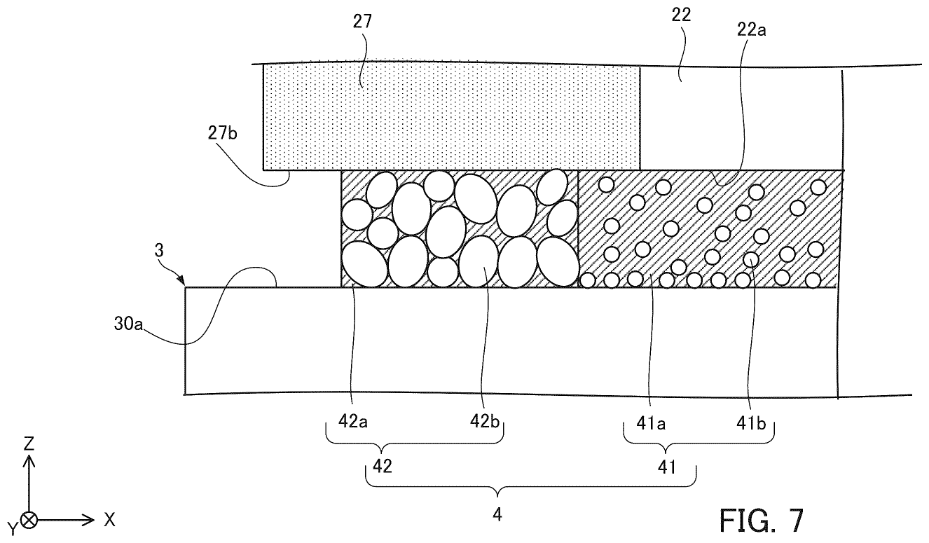

A modification 1-1 to the semiconductor device 1 according to the first embodiment will now be described with reference to FIG. 7. FIG. 7 is an enlarged cross-sectional view of the semiconductor device according to the first embodiment (modification 1-1). Note that FIG. 7 corresponds to FIG. 5 and is an enlarged cross section of the semiconductor device 1 according to modification 1-1.

The bonding member 4 in modification 1-1 also exhibits adhesion and is provided between the lower surface 22a of the metal plate 22 of the semiconductor module 2 and the lower surface 27b of the encapsulating member 27, and the placement surface 30a of the cooling module 3. The bonding member 4 in modification 1-1 also includes the adhesive part 41 and the spacer part 42.

The bonding member 4 in modification 1-1 also includes filler 41b (or “second filler”) in the adhesive part 41. That is, the adhesive part 41 includes a base material 41a and a filler 41b held in the base material 41a.

The base material 41a may be an adhesive. As one example, the adhesive may be an epoxy-based resin. As with the filler 42b of the spacer part 42, the filler 41b may be formed in the shape of spheres or scales, for example. The material of the filler 41b in modification 1-1 may also be the same as the material of the filler 42b of the spacer part 42. In particular, the filler 41b according to modification 1-1 is preferably conductive metal particles. However, the height of the filler 41b in modification 1-1 is lower than the height of the filler 42b of the spacer part 42. The height of the filler 41b may be 1 μm or more and 50 μm or less, and the height of the filler 42b may be 10 μm or more and 300 μm or less. When the filler is spherical in shape, the diameter of the filler 41b is smaller than the diameter of the filler 42b of the spacer part 42. The diameter of the filler 41b may be 1 μm or more and 50 μm or less, and the diameter of the filler 42b may be 10 μm or more and 300 μm or less.

The spacer part 42 in modification 1-1 has the same configuration as the spacer part 42 of the first embodiment. However, as described above, the height of the filler 42b of the spacer part 42 in modification 1-1 is higher than the height of the filler 41b of the adhesive part 41 in modification 1-1. When the filler is spherical in shape, the diameter of the filler 42b of the spacer part 42 in modification 1-1 is larger than the diameter of the filler 41b of the adhesive part 41 in modification 1-1.

Also in the semiconductor device 1 including the bonding member 4 according to modification 1-1, it is possible to control and maintain the thickness of the bonding member 4 at a desired thickness using the filler 42b in the outer periphery of the bonding member 4. As one example, it is possible to control the thickness of the bonding member 4 so that the bonding member 4 has a desired range of thermal conductivity and a desired range of adhesive strength.

By including the (filler 42b included in the) the spacer part 42, the bonding member 4 in modification 1-1 also has a uniform overall thickness and is horizontal. This means that there is no biasing in the heat dissipation by the adhesive part 41 of the bonding member 4, making it possible to uniformly cool the lower surface 22a of the metal plate 22 of the semiconductor module 2. In particular, in modification 1-1, since the adhesive part 41 also includes the conductive filler 41b, the thermal conductivity of the adhesive part 41 is improved, which improves the dissipation of heat. In addition, since the filler 41b contained in the adhesive part 41 is electrically conductive, the lower surface 22a of the metal plate 22 of the semiconductor module 2 and the placement surface 30a of the cooling module 3 become the same potential. Even when a high voltage is applied to this semiconductor device 1, the occurrence of discharging at the bonding member 4 (the adhesive part 41) is prevented.

The adhesive strength of the spacer part 42 is also higher than the adhesive strength of the adhesive part 41. This makes it possible for the spacer part 42 to more reliably and stably bond the lower surface 27b of the encapsulating member 27 of the semiconductor module 2 and the placement surface 30a of the cooling module 3. Stress tends to become concentrated at the outer periphery of the bonding member 4. However, since the adhesive strength of the spacer part 42 is high, peeling is prevented from occurring even when stress becomes concentrated at the spacer part 42. Accordingly, a drop in the reliability of the semiconductor device 1 is prevented.

### Modification 1-2

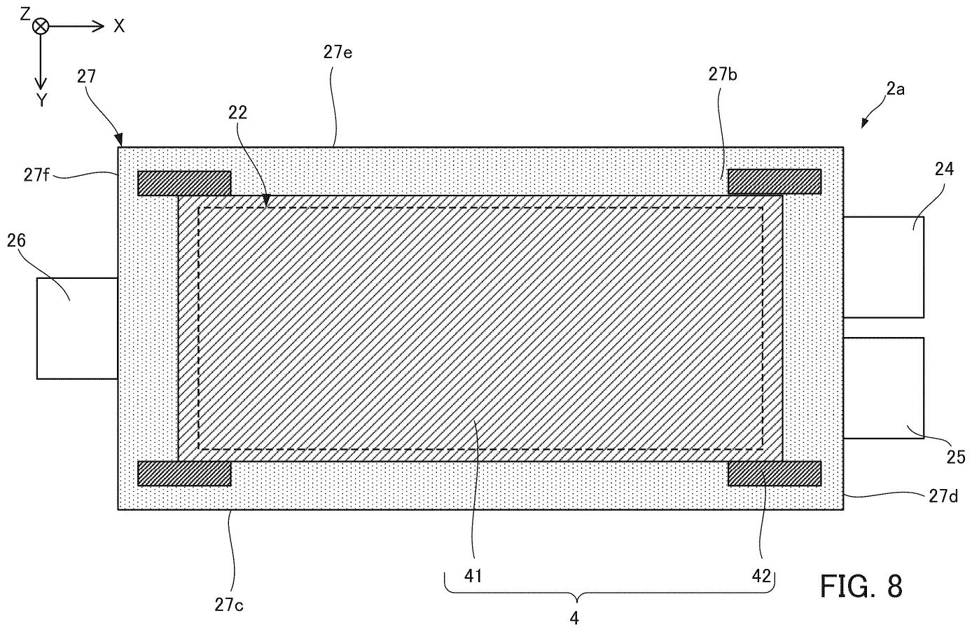

A semiconductor device 1 according to modification 1-2 of the first embodiment will now be described with reference to FIG. 8. FIG. 8 is a rear view of a semiconductor module to which a bonding member has been applied and which is included in the semiconductor device according to the first embodiment (modification 1-2). FIG. 8 corresponds to FIG. 4 and is a rear view of the semiconductor module 2 included in the semiconductor device 1.

The bonding member 4 in modification 1-2 also exhibits adhesion and is provided between the lower surface 22a of the metal plate 22 and the lower surface 27b of the encapsulating member 27 of the semiconductor module 2 and the placement surface 30a of the cooling module 3. The bonding member 4 in modification 1-2 also includes the adhesive part 41 and the spacer part 42. The adhesive part 41 and the spacer part 42 in modification 1-2 may be made of the same materials as in the first embodiment or in modification 1-1.

The adhesive part 41 in modification 1-2 bonds the lower surface 22a and the lower surface 27b of the semiconductor module 2 to the placement surface 30a of the cooling module 3. The adhesive part 41 in modification 1-2 is also in contact with at least the entire lower surface 22a of the metal plate 22 included in the semiconductor module 2.

The spacer part 42 in modification 1-2 is provided at the outer periphery of the adhesive part 41 and bonds the lower surface 27b of the semiconductor module 2 and the placement surface 30a of the cooling module 3. In modification 1-2, the spacer parts 42 are provided at corners of the adhesive part 41 along the long sides of the adhesive part 41 in plan view.

The semiconductor device 1 including the bonding member 4 according to modification 1-2 has the same effects as the first embodiment or modification 1-1 due to the bonding member 4 being made of the same material as the bonding member 4 of the first embodiment or modification 1-1.

So long as the thickness of the bonding member 4 is maintained, the disposed positions of the spacer parts 42 according to modification 1-2 with respect to the adhesive part 41 are not limited to the example in FIG. 8. As another example, the spacer parts 42 may be disposed along at least one of a pair of facing long edges and a pair of facing short edges of the adhesive part 41. It is also possible to dispose the spacer parts 42 according to modification 1-2 so as to form an L-shape at each corner of the adhesive part 41 and cover the outsides of the corners.

### Modification 1-3

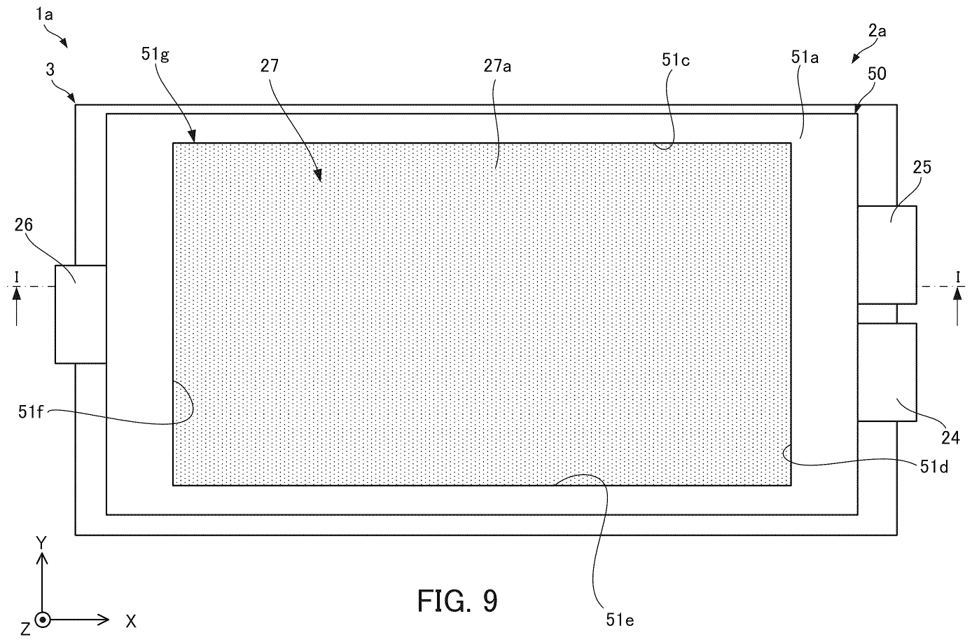

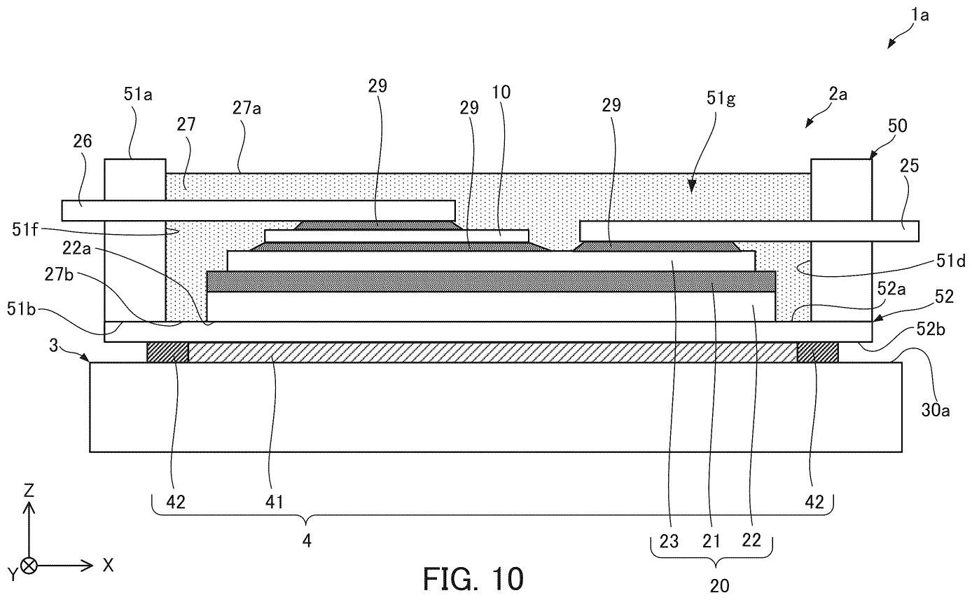

A semiconductor device 1a according to modification 1-3 of the first embodiment will be described with reference to FIGS. 9 and 10. FIG. 9 is a plan view of the semiconductor device according to the first embodiment (modification 1-3). FIG. 10 is a cross-sectional view of the semiconductor device according to the first embodiment (modification 1-3). Note that FIGS. 9 and 10 correspond to FIGS. 1 and 2 for the semiconductor device 1 of the first embodiment, respectively. FIG. 10 is a cross-sectional view taken along a chain line I-I in FIG. 9.

The semiconductor device 1a according to modification 1-3 includes a semiconductor module 2a, the cooling module 3, and the bonding member 4 that bonds the semiconductor module 2a and the cooling module 3. The cooling module 3 and the bonding member 4 included in the semiconductor device 1a according to modification 1-3 have the same configurations as the cooling module 3 and the bonding member 4 according to the first embodiment and modifications 1-1 and 1-2.

That is, the semiconductor module 2a of the semiconductor device 1a according to modification 1-3 differs from the semiconductor modules 2 of the first embodiment and modifications 1-1 and 1-2. The semiconductor module 2a in modification 1-3 includes the insulated circuit board 20, the semiconductor chip 10, and the external terminals 24, 25, and 26. In the semiconductor module 2a, the insulated circuit board 20 and the semiconductor chip 10 are accommodated within a case 50 and a base plate 52, and the inside of the case 50 and the base plate 52 is encapsulated with the encapsulating member 27. The insulated circuit board 20, the semiconductor chip 10, and the external terminals 24, 25, and 26 are the same as those of the first embodiment described with reference to FIGS. 1 to 5, and are assembled in the same manner. The encapsulating member 27 is also the same as in the first embodiment described with reference to FIGS. 1 to 5.

The case 50 has a frame shape. The case 50 includes an upper surface 51a and a lower surface 51b, and includes inner wall surfaces 51c to 51f that surround four sides of a housing region 51g that connects the upper surface 51a and the lower surface 51b in order. The external terminals 24 and 25 extend outward from the inner wall surface 51d of the case 50, and the external terminal 26 extends outward from the inner wall surface 51f. The case 50 is integrally molded with the external terminals 24, 25, and 26 by injection molding using a thermoplastic resin containing a filler. Example resins include polyphenylene sulfide (PPS) resin, polybutylene terephthalate (PBT) resin, and polyamide (PA) resin. Examples of the filler include glass fibers, glass beads, calcium carbide, talc, magnesium oxide, and aluminum hydroxide.

The base plate 52 is rectangular in shape in plan view and includes an upper surface 52a and a lower surface 52b. The outer shape of the base plate 52 in plan view may have the same size as the outer shape of the case 50. The base plate 52 is made of a metal with superior thermal conductivity. Example materials include copper, aluminum, and an alloy containing at least one of these metals. A plating treatment may also be performed on the surfaces of the metal plate 22 to improve corrosion resistance. Examples of such a plating material include nickel, nickel-phosphorus alloy, and nickel-boron alloy.

The insulated circuit board 20 on which the semiconductor chip 10 is disposed is bonded to the upper surface 52a of the base plate 52 via the bonding member described earlier (not depicted). The lower surface 51b of the case 50 is bonded to an outer edge portion of the upper surface 52a of the base plate 52 via adhesive (not depicted). Accordingly, the insulated circuit board 20 on which the semiconductor chip 10 is disposed is housed in the housing region 51g surrounded by the case 50 and the base plate 52. When doing so, the external terminal 26 is bonded via the bonding member 29 to the main electrode on the front surface of the semiconductor chip 10, and the external terminals 24 and 25 (the external terminal 25 is illustrated in FIG. 10) are bonded via the bonding member 29 to the conductive circuit pattern 23 of the insulated circuit board 20. The housing region 51g is also filled with the encapsulating member 27 to encapsulate the insulated circuit board 20, the semiconductor chip 10, and the external terminals 24 to 26.

Aside from the materials described in the first embodiment, the encapsulating member 27 in modification 1-3 may be made of silicone gel. However, when the semiconductor module 2a does not include the base plate 52, the inside of the housing region 51g of the case 50 is encapsulated with the encapsulating member 27 described in the first embodiment. When doing so, the lower surface 51b of the case 50, the lower surface 22a of the metal plate 22 of the insulated circuit board 20, and the lower surface 27b of the encapsulating member 27 may be flush.

The bonding member 4 is disposed between the semiconductor module 2a and the placement surface 30a of the cooling module 3. The adhesive part 41 of the bonding member 4 is in contact with at least the lower surface 52b of the base plate 52 corresponding to the lower surface 22a of the metal plate 22 of the semiconductor module 2a. The spacer part 42 of the bonding member 4 may be provided on the outer periphery of the adhesive part 41 and contact the lower surface 52b of the base plate 52.

Note that when the semiconductor module 2a does not include the base plate 52, the adhesive part 41 of the bonding member 4 is in direct contact with at least the lower surface 22a of the metal plate 22 of the semiconductor module 2. The spacer part 42 of the bonding member 4 may be provided at the outer periphery of the adhesive part 41 and may be in contact with the lower surface 27b of the encapsulating member 27 and the lower surface 51b of the case 50. The spacer part 42 may be in contact the lower surface 51b of the case 50 up to the outer periphery.

This means that even with the semiconductor device 1a in which the semiconductor module 2a includes the case 50 (and the base plate 52) as in modification 1-3, the same effects as the first embodiment and modifications 1-1 and 1-2 are obtained. Note that the case 50 (and the base plate 52) included in the semiconductor module 2a is merely one example. Aside from the case 50, a case used as an outer enclosure of the semiconductor module 2a may be used.

### Second Embodiment

In the second embodiment, a configuration where the bonding member 4 does not include the spacer part 42 but includes a spacer member between the semiconductor module 2 and the cooling module 3 in the semiconductor device 1 according to the first embodiment will be described with reference to FIGS. 1, 11, and 12.

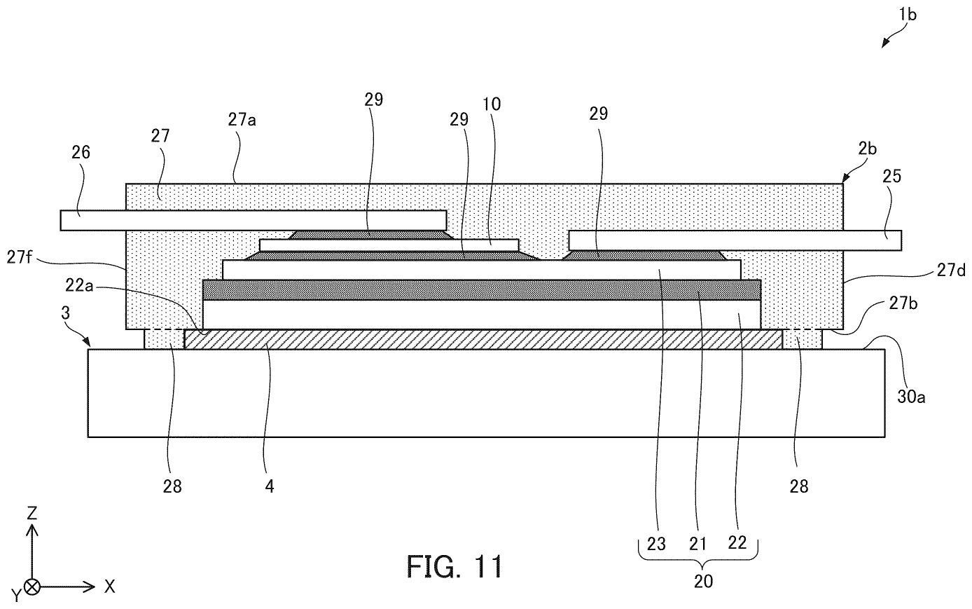

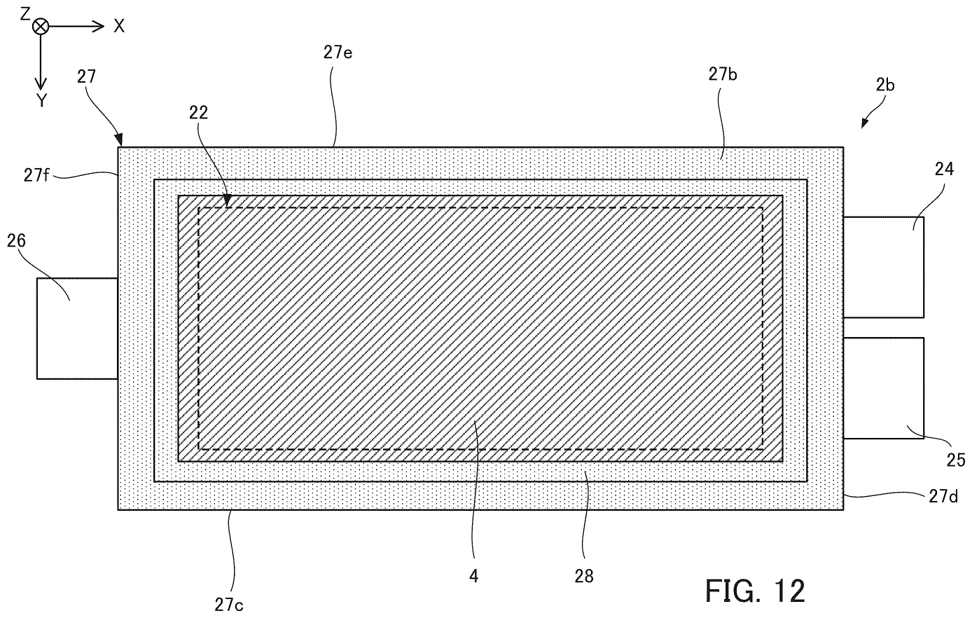

FIG. 11 is a cross-sectional view of the semiconductor device according to the second embodiment. FIG. 12 is a rear view of a semiconductor module to which a bonding member has been applied and which is included in the semiconductor device according to the second embodiment. In plan view, the semiconductor device 1b according to the second embodiment is the same as the first embodiment depicted in plan view in FIG. 1. FIG. 11 is a cross-sectional view taken along the chain line I-I for a case where FIG. 1 depicts the semiconductor device 1b. In FIG. 12, the range of the metal plate 22 is indicated by a broken line.

As depicted in FIG. 11, the semiconductor device 1b includes a semiconductor module 2b, the cooling module 3, and the bonding member 4 that fixes the semiconductor module 2b and the cooling module 3. Note that in addition to these components, the semiconductor device 1b may also include other components as needed.

The semiconductor module 2b includes the semiconductor chip 10, the insulated circuit board 20, the external terminals 24, 25, and 26, and the encapsulating member 27 that encapsulates these components. The outer ends of the external terminals 24, 25, and 26 are exposed from the encapsulating member 27. The semiconductor chip 10, the insulated circuit board 20, and the external terminals 24, 25, and 26 have the same configurations as in the first embodiment and may be assembled in the same way as in the first embodiment.

As in the case of the first embodiment, the encapsulating member 27 may be a thermosetting resin containing a filler. Also as in the first embodiment, the encapsulating member 27 may be shaped as a rectangular cuboid and includes the upper surface 27a, the lower surface 27b, and the long side surface 27c, the short side surface 27d, the long side surface 27e, and the short side surface 27f that surround the four sides of the upper surface 27a and the lower surface 27b in that order. The outer ends of the external terminals 24 and 25 and the external terminal 26 extend outward from the short side surface 27d and the short side surface 27f of the encapsulating member 27. The lower surface 22a of the metal plate 22 of the insulated circuit board 20 is exposed from the lower surface 27b of the encapsulating member 27.

The encapsulating member 27 in this second embodiment has a spacer 28 (spacer member) integrally provided on the lower surface 27b. The spacer 28 may be made of the same material as the encapsulating member 27. The spacer 28 surrounds the lower surface 22a of the metal plate 22 exposed from the lower surface 27b. In the second embodiment, the outer periphery of the spacer 28 is located inside the outer periphery of the lower surface 27b in plan view. However, the outer periphery of the spacer 28 is not limited to this configuration, and may extend up to the outer periphery of the lower surface 27b. The height (in the ±Z direction) of the spacer 28 is uniform across the entire spacer 28.

The bonding member 4 exhibits adhesion and is provided between the lower surface 22a of the metal plate 22 and the lower surface 27b of the encapsulating member 27 of the semiconductor module 2b and the placement surface 30a of the cooling module 3 within a range surrounded by the spacer 28 of the semiconductor module 2b.

The bonding member 4 is in contact with at least the entire lower surface 22a of the metal plate 22 included in the semiconductor module 2. For this reason, the bonding member 4 may be rectangular in shape in a plan view similar to the lower surface 22a of the metal plate 22. In this case, the spacer 28 is provided on the lower surface 27b of the encapsulating member 27 along (and possibly contacting) the short edges and the long edges of the lower surface 22a of the metal plate 22 in plan view.

Note that inner corners of the spacer 28 may be chamfered into rounded shapes. Corners of the bonding member 4 are also chamfered into rounded shapes in keeping with the shape of the spacer 28. This means that even when stress is generated when the semiconductor device 1b is distorted, stress that acts on corners of the bonding member 4 is alleviated. As a result, the occurrence of damage, such as cracking and peeling of the bonding member 4, is reduced.

The bonding member 4 may be made of the same material as the adhesive part 41 of the first embodiment and modification 1-1. That is, the base material of the bonding member 4 is an adhesive. As one example, the adhesive may be epoxy-based resin. Alternatively, the bonding member 4 may further include a filler. The filler may be formed in the shape of spheres or scales, for example. The filler is preferably the conductive metal particles described in modification 1-1. The bonding member 4 has higher thermal conductivity than the spacer 28.

The semiconductor device 1b includes the semiconductor module 2b, which includes the lower surface 22a of the metal plate 22 and the lower surface 27b of the encapsulating member 27, the cooling module 3, which includes the placement surface 30a on which the lower surfaces 22a and 27b of the semiconductor module 2b are placed, and the bonding member 4 which is provided between the placement surface 30a of the cooling module 3 and the lower surfaces 22a and 27b of the semiconductor module 2b and exhibits adhesion. The spacer 28 is also formed on the lower surface 27b of the encapsulating member 27 of the semiconductor module 2b and is provided between a part of the lower surface 27b of the encapsulating member 27 of the semiconductor module 2b around the outer periphery of the bonding member 4 and the placement surface 30a of the cooling module 3. This makes it possible to control and maintain the thickness of the bonding member 4 at a desired thickness using the spacer 28.

The spacer 28 is formed when the semiconductor module 2b is manufactured. This means that the semiconductor device 1b is manufactured by merely disposing the semiconductor module 2b via the bonding member 4 on the cooling module 3 with no need for a step of introducing the spacer 28. This makes it possible to manufacture the semiconductor device 1b without an increase in manufacturing cost.

In addition, due to the spacer 28, the bonding member 4 has a uniform overall thickness and is horizontal. This makes it possible for the bonding member 4 to uniformly cool the lower surface 22a of the metal plate 22 of the semiconductor module 2b with no biasing in the dissipation of heat. In particular, when the bonding member 4 contains a filler, the thermal conductivity is improved, which further enhances heat dissipation. The bonding member 4 also causes the lower surface 27b of the encapsulating member 27 of the semiconductor module 2b to stick to the placement surface 30a of the cooling module 3. Since the circumference of the bonding member 4 is surrounded by the spacer 28, leakage to the outside is prevented when a wet bonding member 4 is spread by applying pressure before curing. This prevents a drop in reliability of the semiconductor device 1b.

Note that in the semiconductor device 1a according to modification 1-3 depicted in FIG. 10, as one example, an annular spacer that is continuous around the housing region 51g may be provided on the lower surface 51b of the case 50 so as to be integrated with the case 50, and the bonding member 4 may be provided in a region surrounded by such spacer.

### Third Embodiment

In this third embodiment, a configuration where the spacer is provided not on the lower surface 27b of the encapsulating member 27 of the semiconductor module 2 but on the placement surface 30a of the cooling module 3 in the semiconductor device 1b of the second embodiment will be described with reference to FIGS. 1, 13, and 14.

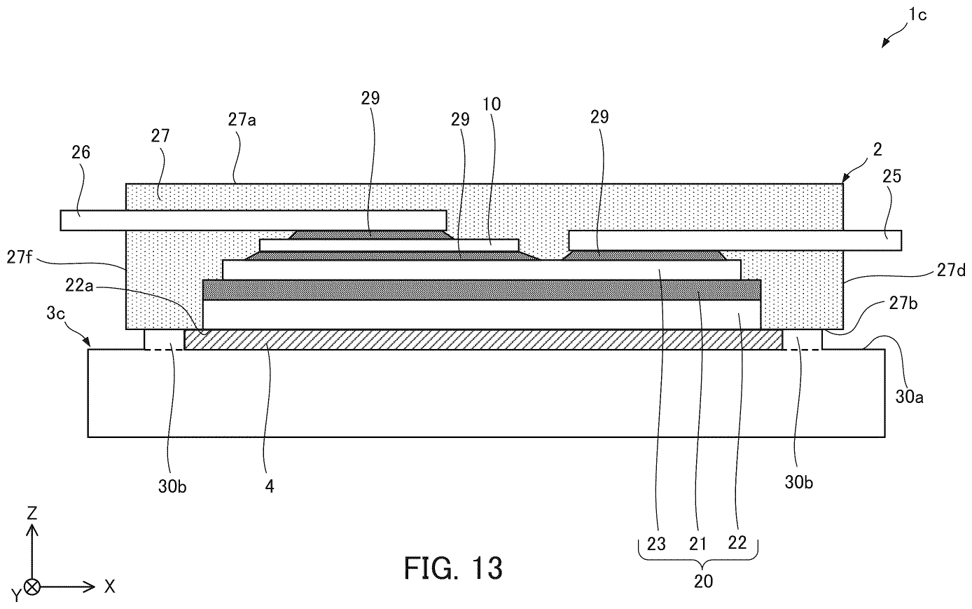

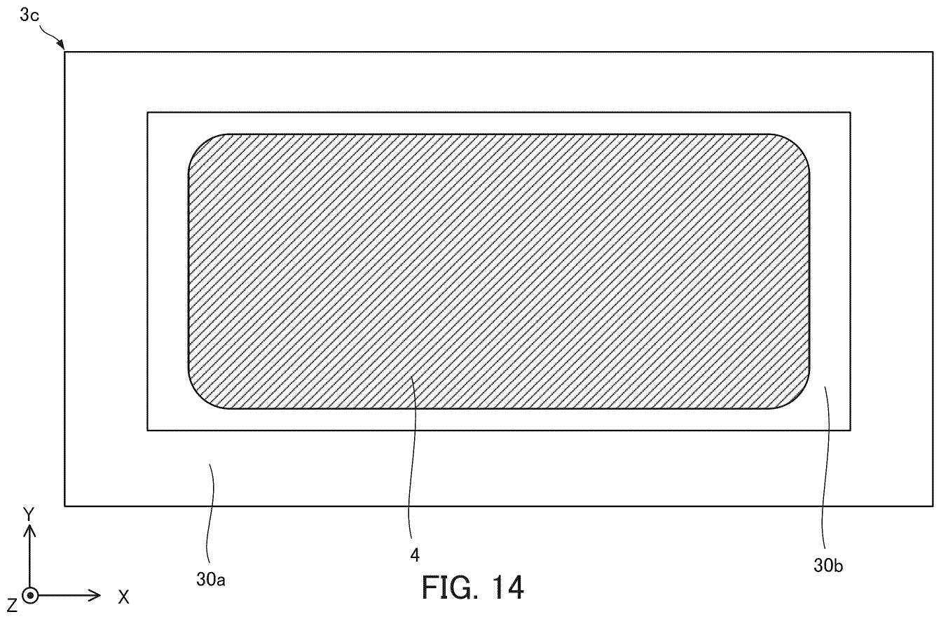

FIG. 13 is a cross-sectional view of the semiconductor device according to the third embodiment. FIG. 14 is a plan view of a cooling module to which a bonding member is applied and which is included in the semiconductor device according to the third embodiment. A plan view of a semiconductor device 1c according to the third embodiment is depicted in FIG. 1. FIG. 13 is a cross-sectional view taken along the chain line I-I for a case where FIG. 1 depicts the semiconductor device 1c.

As depicted in FIG. 13, the semiconductor device 1c includes the semiconductor module 2, a cooling module 3c, and the bonding member 4 that fixes the semiconductor module 2 and the cooling module 3c. Note that the semiconductor device 1c may also include other components as needed in addition to these components.

The semiconductor module 2 may have the same configuration as the semiconductor module 2 described in the first embodiment. The semiconductor module 2 may alternatively be the semiconductor module 2a according to modification 1-3 depicted in FIG. 10.

The cooling module 3c also includes, on an upper surface, a placement surface 30a on which the semiconductor module 2 is placed. The placement surface 30a of the third embodiment includes a spacer 30b (spacer member). The spacer 30b may be made of the same material as the placement surface 30a. The spacer 30b is provided on the placement surface 30a in a continuous annular shape so as to surround the outer periphery of the lower surface 22a of the metal plate 22 exposed from the lower surface 27b of the encapsulating member 27 of the semiconductor module 2 when the cooling module 3c is attached to the semiconductor module 2. Accordingly, the spacer 30b comes into contact with the lower surface 27b of the encapsulating member 27 of the semiconductor module 2. In the third embodiment, the outer periphery of the spacer 30b is located inside the outer periphery of the lower surface 27b of the semiconductor module 2 in plan view. The outer periphery of the spacer 30b is not limited to this configuration, and may extend to the outer periphery of the lower surface 27b. Inner corners of the continuous annular spacer 30b may be chamfered into rounded shapes as depicted in FIG. 14. The height (in the ±Z direction) of the spacer 30b is uniform across the entire spacer 30b.

The bonding member 4 may be made of the same material as the bonding member 4 of the second embodiment, and may contain a conductive filler. The bonding member 4 is also provided between the lower surface 22a of the metal plate 22 and the lower surface 27b of the encapsulating member 27 of the semiconductor module 2 and the placement surface 30a of the cooling module 3 within the range surrounded by the spacer 30b of the cooling module 3c.

The bonding member 4 is in contact with at least the entire lower surface 22a of the metal plate 22 included in the semiconductor module 2. For this reason, the bonding member 4 may be rectangular in shape in plan view as with the lower surface 22a of the metal plate 22. In the third embodiment, inner corners of the spacer 30b may be chamfered into rounded shapes. Corner portions of the bonding member 4 are also chamfered into rounded shapes in keeping with the shape of the spacer 30b. This means that even when stress is generated when the semiconductor device 1c is distorted, stress that acts on corners of the bonding member 4 is alleviated. As a result, the occurrence of damage such as cracking and peeling of the bonding member 4 is reduced.

This semiconductor device 1c includes the semiconductor module 2, which includes the lower surface 22a of the metal plate 22 and the lower surface 27b of the encapsulating member 27, the cooling module 3c, which includes the placement surface 30a on which the lower surfaces 22a and 27b of the semiconductor module 2 are placed, and the bonding member 4 that is provided between the placement surface 30a of the cooling module 3c and the lower surfaces 22a and 27b of the semiconductor module 2 and exhibits adhesion. The semiconductor device 1c also includes the spacer 30b that is formed on the placement surface 30a of the cooling module 3 and provided between a part of the placement surface 30a of the cooling module 3c around the outer periphery of the bonding member 4 and the lower surface 27b of the encapsulating member 27 of the semiconductor module 2. This makes it possible to control and maintain the thickness of the bonding member 4 at a desired thickness using the spacer 30b. In addition, since the circumference of the bonding member 4 is closed by the spacer 28, leakage from the semiconductor device 1c when the wet bonding member 4 is spread by applying pressure before curing is prevented. This prevents a drop in reliability of the semiconductor device 1c as in the second embodiment.

Modifications to the spacer 30b according to the third embodiment will now be described. Aside from the spacer 30b, the remaining configuration may be the same as in the semiconductor device 1c of the third embodiment. The following modifications may also be applied in the same way to the spacer 28 in the second embodiment. Such modifications may also be applied to the spacer part 42 in the first embodiment.

### Modification 3-1

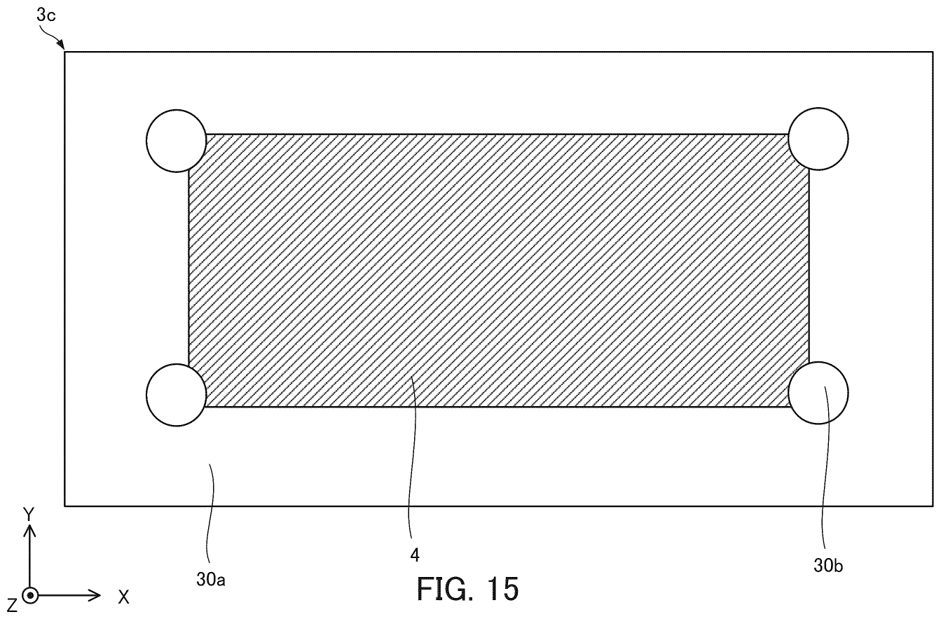

Modification 3-1 of the third embodiment will now be described with reference to FIG. 15. FIG. 15 is a plan view of a cooling module to which a bonding member has been applied and which is included in the semiconductor device according to the third embodiment (modification 3-1). Note that FIG. 15 corresponds to FIG. 14.

The spacer 30b in modification 3-1 is provided in regions of the placement surface 30a of the cooling module 3 that correspond to the peripheries of corner portions of the lower surface 22a of the metal plate 22. In this case, the spacer 30b may be in the shape of columns. As example shapes, such columns may be cylinders, prisms, cones, or pyramids. Modification 3-1 here illustrates a case where cylinders are used. The spacer 30b is provided with the same height at each corner.

With the semiconductor device 1c that includes such spacer 30b, it is also possible to control and maintain the thickness of the bonding member 4 at a desired thickness using the spacer 30b. This prevents a drop in the reliability of the semiconductor device 1c in the same way as the third embodiment.

### Modification 3-2

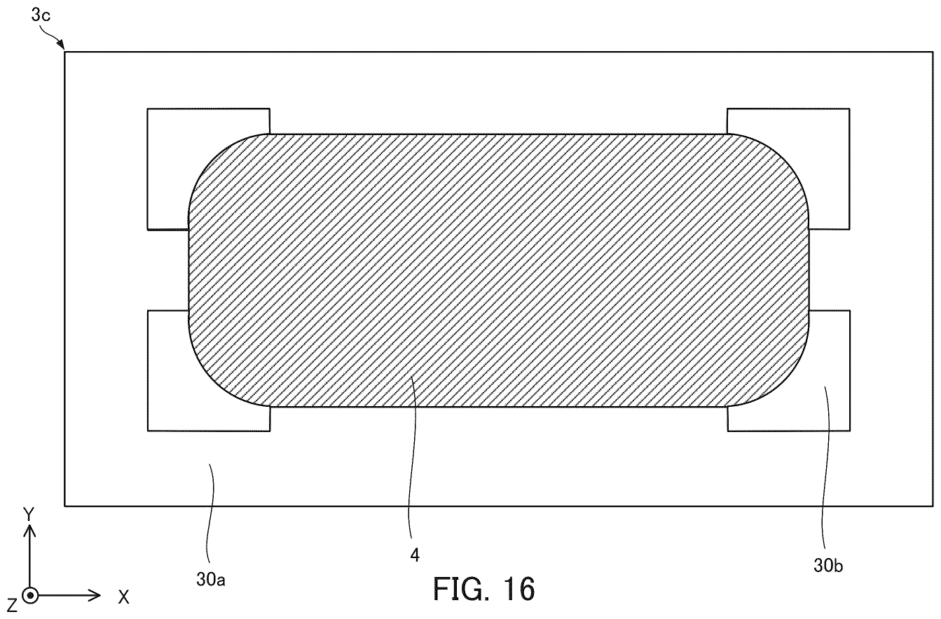

Modification 3-2 of the third embodiment will now be described with reference to FIG. 16. FIG. 16 is a plan view of a cooling module to which a bonding member has been applied and which is included in the semiconductor device according to the third embodiment (modification 3-2). Note that FIG. 16 corresponds to FIG. 14.

The spacer 30b in modification 3-2 is provided in regions of the placement surface 30a of the cooling module 3c correspond to the peripheries of corner portions of the lower surface 22a of the metal plate 22. In particular, unlike the spacer 30b in the third embodiment, the spacer 30b in modification 3-2 is provided at corner portions only with gaps being provided in between. Here, for the spacer 30b, gaps are provided at both a pair of facing short edges and a pair of facing long edges of the lower surface 22a of the metal plate 22. That is, the spacer 30b of modification 3-2 is provided in an annular shape aside from edge portions on the long sides and the short sides of the region of the placement surface 30a of the cooling module 3c. Each part of the spacer 30b is L-shaped and is provided along a long side and a short side of the lower surface 22a of the metal plate 22 at a corner of the lower surface 22a of the metal plate 22. The inner corner of each spacer 30b is chamfered into a rounded shape. The spacer 30b is provided with the same height at each corner.

With the semiconductor device 1c including the spacer 30b in modification 3-2, it is also possible to control and maintain the thickness of the bonding member 4 at a desired thickness using the spacer 30b. Since the inner corner portions of the spacer 30b are chamfered into rounded shapes, concentration of stress at corner portions of the spacer 30b is suppressed, and occurrence of abnormal stress acting on the entire semiconductor device 1c is prevented. This prevents a drop in the reliability of the semiconductor device 1c in the same way as in the third embodiment.

### Modification 3-3

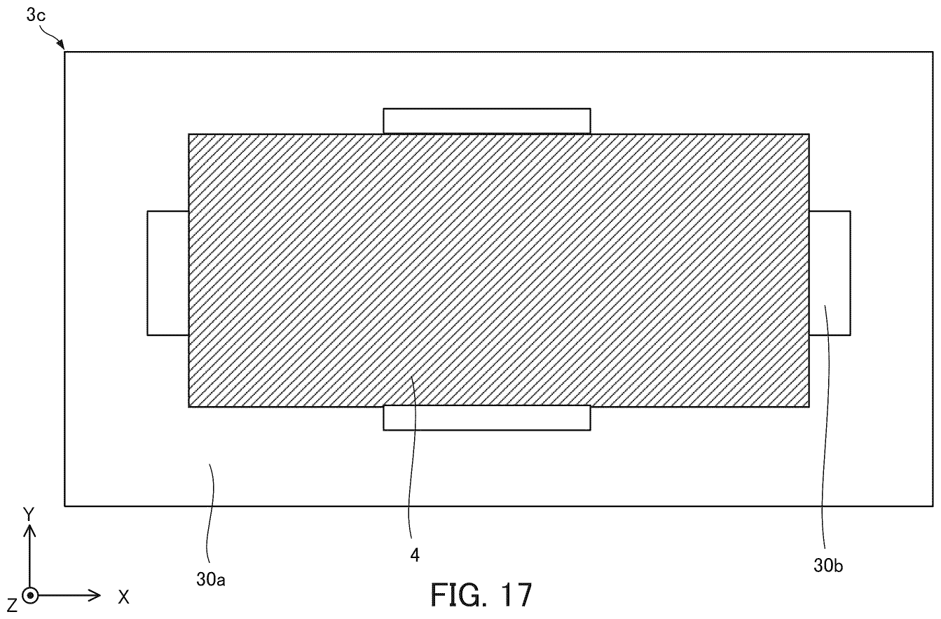

Modification 3-3 of the third embodiment will now be described with reference to FIG. 17. FIG. 17 is a plan view of a cooling module to which a bonding member has been applied and which is included in the semiconductor device according to the third embodiment (modification 3-3). Note that FIG. 17 corresponds to FIG. 14.

The spacer 30b in modification 3-3 is provided in the centers of regions of the placement surface 30a of the cooling module 3c that correspond to the pair of facing long sides and the pair of facing short sides of the lower surface 22a of the metal plate 22. That is, the spacer 30b in modification 3-3 is provided in regions of the placement surface 30a of the cooling module 3c corresponding to an annular part which excludes corner portions of the lower surface 22a of the metal plate 22. The parts of the spacer 30b are linear in shape and are provided along a pair of long sides and a pair of short sides of the lower surface 22a of the metal plate 22. Each part of the spacer 30b has the same height.

With the semiconductor device 1c including the spacer 30b in modification 3-3, it is also possible to control and maintain the thickness of the bonding member 4 at a desired thickness using the spacer 30b. Since the spacer 30b is not provided at corner portions of the bonding member 4, stress is not particularly concentrated at corner portions of the bonding member 4, and occurrence of abnormal stress acting on the entire semiconductor device 1c is prevented. This also prevents a drop in the reliability of the semiconductor device 1c in the same way as in the second and third embodiments.

### Fourth Embodiment

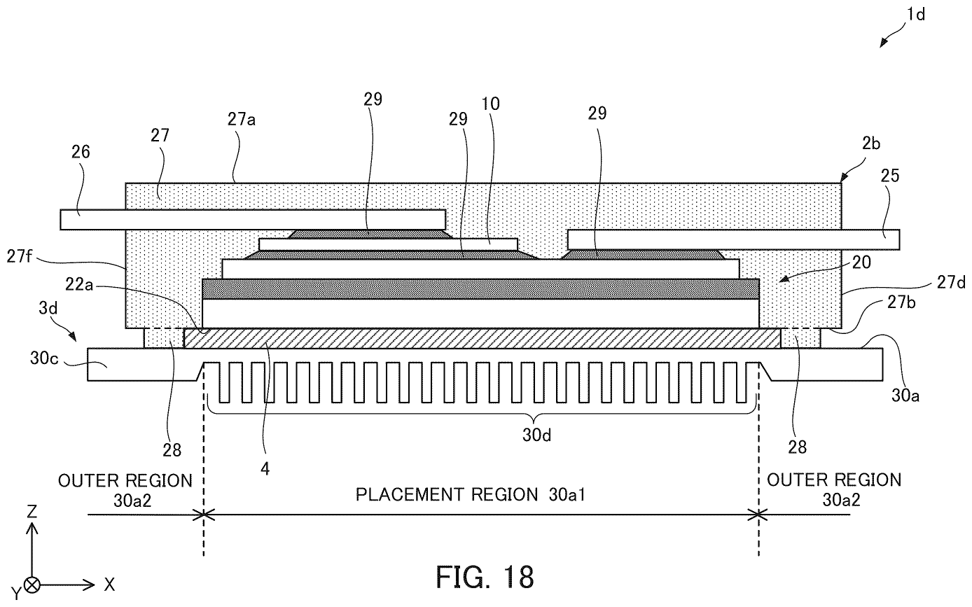

In the fourth embodiment, a semiconductor device 1d, where a cooling module including a plurality of fins is attached to the semiconductor module 2b of the second embodiment, will now be described with reference to FIGS. 1 and 18. FIG. 18 is a cross-sectional view of a semiconductor device according to the fourth embodiment. A plan view of a semiconductor device 1d according to the fourth embodiment is depicted in FIG. 1. FIG. 18 is a cross-sectional view taken along the chain line I-I for a case where FIG. 1 depicts the semiconductor device 1d.

As depicted in FIG. 18, the semiconductor device 1d of the fourth embodiment also includes the semiconductor module 2b, a cooling module 3d, and the bonding member 4 that fixes the semiconductor module 2b and the cooling module 3d. Note that the semiconductor device 1d may also include other components as needed in addition to these components.

The semiconductor module 2b and the bonding member 4 are the same as the semiconductor module 2b and the bonding member 4 described in the second embodiment. The cooling module 3d includes a heat dissipation plate 30c and a plurality of fins 30d. The heat dissipation plate 30c includes the placement surface 30a on which the semiconductor module 2b is placed. The heat dissipation plate 30c may be made of a metal with superior thermal conductivity. Example metals include copper, aluminum, or an alloy containing at least one of these metals. Surfaces of the heat dissipation plate 30c may be plated as described above to improve corrosion resistance. The heat dissipation plate 30c includes a placement region 30a1 where the semiconductor module 2b is placed and an outer region 30a2 located outside the placement region 30a1, the placement region 30a1 being thinner than the outer region 30a2. The plurality of fins 30d are integrally provided on an opposite side to placement surface 30a of the heat dissipation plate 30c. Accordingly, the plurality of fins 30d may also be made of the same material as the heat dissipation plate 30c. The plurality of fins 30d may also be plated in the same way as the heat dissipation plate 30c. The semiconductor module 2b is bonded by the bonding member 4 to the placement surface 30a of the cooling module 3d, which is referred to as “open fins”. When doing so, the spacer 28 of the semiconductor module 2b comes into contact with the placement surface 30a of the outer region 30a2 of the heat dissipation plate 30c.

Also in the semiconductor device 1d, it is possible to control and maintain the thickness of the bonding member 4 at a desired thickness using the spacer 28. In addition, the spacer 28 of the semiconductor module 2b is disposed in the outer region 30a2 where the thickness of the heat dissipation plate 30c is thicker. The semiconductor device 1d may be distorted, and stress may be applied to the heat dissipation plate 30c via the spacer 28. In this case, since the outer region 30a2 of the heat dissipation plate 30c is thicker and stronger than other parts, the heat dissipation plate 30c is not caused to sink by the spacer 28, which reduces damage. This prevents a drop in the reliability of the semiconductor device 1d in the same way as in the second embodiment.

### Fifth Embodiment

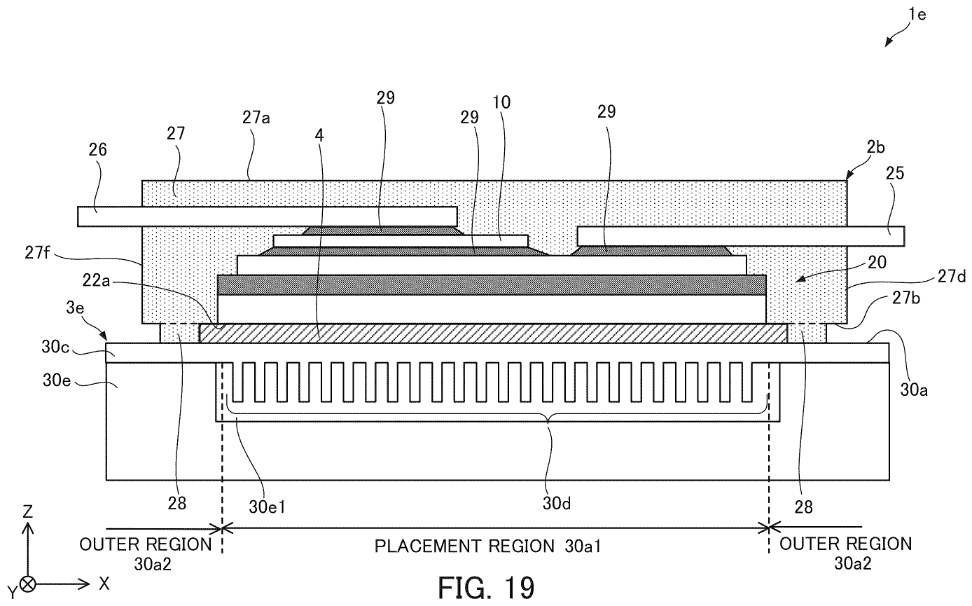

In the fifth embodiment, a semiconductor device 1e where a cover is attached to the cooling module 3d of the fourth embodiment will be described with reference to FIGS. 1 and 19. FIG. 19 is a cross-sectional view of a semiconductor device according to the fifth embodiment. A plan view of a semiconductor device 1e according to the fifth embodiment is depicted in FIG. 1. FIG. 19 is a cross-sectional view taken along the chain line I-I for a case where FIG. 1 depicts the semiconductor device 1e.

As depicted in FIG. 19, the semiconductor device 1e according to the fifth embodiment includes the semiconductor module 2b, a cooling module 3e, and the bonding member 4 that fixes the semiconductor module 2b and the cooling module 3e. Note that, in addition to these components, the semiconductor device 1e may also include other components as needed.

The semiconductor module 2b and the bonding member 4 are the same as in the fourth embodiment. The cooling module 3e includes the heat dissipation plate 30c, the plurality of fins 30d, and a cover 30e. The heat dissipation plate 30c includes the placement surface 30a on which the semiconductor module 2b is placed. The heat dissipation plate 30c may have a uniform thickness across the entire heat dissipation plate 30c. The plurality of fins 30d are integrally provided on an opposite side to placement surface 30a of the heat dissipation plate 30c. The heat dissipation plate 30c and the plurality of fins 30d are made of metal with superior thermal conductivity. Example metals include copper, aluminum, or an alloy containing at least one of these metals. The surfaces of the heat dissipation plate 30c and the plurality of fins 30d may also be plated as described earlier to improve corrosion resistance.

The cover 30e is shaped as a box, and has a recessed flow path region 30e1 formed at the center. An upper surface of the cover 30e is in contact with a surface of the outer region 30a2 of the heat dissipation plate 30c that is opposite to the placement surface 30a, and the plurality of fins 30d are accommodated in the flow path region 30e1. The semiconductor module 2b is bonded by the bonding member 4 to the placement surface 30a of the cooling module 3e, which is referred to as “closed fins”. When doing so, the spacer 28 of the semiconductor module 2b comes into contact with placement surface 30a of the outer region 30a2 included on the heat dissipation plate 30c to which the cover 30e is attached.

Note that, in the cooling module 3e, a refrigerant flows into an inlet (not illustrated) that communicates with the flow path region 30e1, with the refrigerant that has flowed from the inlet flowing inside the flow path region 30e1. While flowing inside the flow path region 30e1, the refrigerant receives heat conducted from the semiconductor module 2b via the plurality of fins 30d. The refrigerant that has flowed through the flow path region 30e1 flows out from an outlet (not depicted) that communicates with the flow path region 30e1. In this way, the semiconductor module 2b is cooled. Note that, as examples, water, antifreeze (an aqueous solution of ethylene glycol), or long life coolant is used as the refrigerant.

With the semiconductor device 1e, it is also possible to control and maintain the thickness of the bonding member 4 at a desired thickness using the spacer 28. The spacer 28 of the semiconductor module 2b is disposed in the outer region 30a2 of the heat dissipation plate 30c contacted by the cover 30e. The semiconductor device 1e may be distorted and stress may be applied to the heat dissipation plate 30c via the spacer 28. In this case, since the outer region 30a2 of the heat dissipation plate 30c is provided with the cover 30e and is thicker and stronger than other parts, the heat dissipation plate 30c is not caused to sink by the spacer 28, which reduces damage. This prevents a drop in the reliability of the semiconductor device 1e in the same way as in the second embodiment.

According to the disclosed techniques, it is possible to maintain the thickness of a bonding member that bonds a semiconductor module and a cooling module and to maintain a desired level of heat dissipation.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor module having a lower surface;
a cooling module including a placement surface on which the semiconductor module is placed, the placement surface being in contact with the lower surface of the semiconductor module; and
a bonding member provided between the placement surface of the cooling module and the lower surface of the semiconductor module,
the bonding member including:
an adhesive part that bonds the lower surface of the semiconductor module and the placement surface of the cooling module, and
a spacer part that is provided at a periphery of the adhesive part, bonds the lower surface of the semiconductor module and the placement surface of the cooling module, and contains a first filler.

2. The semiconductor device according to claim 1,
wherein the adhesive part of the bonding member contains a second filler having a lower height than the first filler.

3. The semiconductor device according to claim 2,
wherein the adhesive part has higher thermal conductivity than the spacer part.

4. The semiconductor device according to claim 2,
wherein each of the first filler and the second filler is made of a conductive material as a main component thereof.

5. The semiconductor device according to claim 1,
wherein the spacer part of the bonding member has higher adhesive strength than the adhesive part.

6. The semiconductor device according to claim 1, wherein
the semiconductor module further includes a metal plate, which has a main surface that is exposed from the lower surface of the semiconductor module, both the main surface of the metal plate and the lower surface of the semiconductor module being in contact with the placement surface of the cooling module, and
the adhesive part bonds the entire main surface of the metal plate and the placement surface of the cooling module.

7. The semiconductor device according to claim 6,
wherein the spacer part is provided in a continuous annular shape around the periphery of the adhesive part.

8. The semiconductor device according to claim 6, wherein
the main surface of the metal plate is rectangular in a plan view of the semiconductor device, and
the spacer part is provided at each of four corners of the adhesive part.

9. The semiconductor device according to claim 1, wherein
the semiconductor module further includes an insulated circuit board that includes:
a metal plate at the lower surface of the semiconductor module;
an insulating layer provided on a surface of the metal plate opposite to the lower surface; and
a conductive circuit pattern provided on the insulating layer.

10. The semiconductor device according to claim 9,
wherein the insulating layer is made of resin.

11. A semiconductor device, comprising:
a semiconductor module having a lower surface;
a cooling module including a placement surface on which the semiconductor module is placed, the placement surface being in contact with the lower surface of the semiconductor module;
a bonding member provided between the placement surface of the cooling module and the lower surface of the semiconductor module; and
a spacer member provided at a periphery of the bonding member between the placement surface of the cooling module and the lower surface of the semiconductor module.

12. The semiconductor device according to claim 11, wherein
the semiconductor module further includes a metal plate, which has a main surface that is exposed from the lower surface of the semiconductor module, both the main surface of the metal plate and the lower surface of the semiconductor module being in contact with the placement surface of the cooling module, and
the bonding member bonds the entire main surface of the metal plate and the placement surface of the cooling module.

13. The semiconductor device according to claim 12,
wherein the spacer member is provided in a continuous annular shape around the periphery of the bonding member.

14. The semiconductor device according to claim 13,
wherein the spacer member has corners on a bonding member side thereof, the corners being chamfered into rounded shapes.

15. The semiconductor device according to claim 12, wherein
the main surface of the metal plate is rectangular in a plan view of the semiconductor device, and
the spacer member is continuously provided around the periphery of the bonding member in the plan view except for parts corresponding to four sides of the main surface of the metal plate.

16. The semiconductor device according to claim 12, wherein
the main surface of the metal plate is rectangular in a plan view of the semiconductor device, and
the spacer member is continuously provided around the periphery of the bonding member in the plan view except for parts corresponding to four corners of the main surface of the metal plate.

17. The semiconductor device according to claim 12, wherein
the cooling module includes:
a heat dissipation plate that is made of metal, and has a surface that is the placement surface of the cooling module; and
a plurality of heat dissipation fins formed on the heat dissipation plate, at a side thereof opposite to the semiconductor module,
the heat dissipation plate includes:
a placement region in which the metal plate is placed, and
an outer region that is outside the placement region,
the heat dissipation fins are located in the placement region,
a thickness of the outer region of the heat dissipation plate is greater than a thickness of the placement region of the heat dissipation plate, and
the spacer member is located in the outer region of the placement surface.

18. The semiconductor device according to claim 11, wherein
the semiconductor module includes an outer enclosure including the lower surface, and
the spacer member is made of a same material as the outer enclosure and is integrally formed with the lower surface of the semiconductor module.

19. The semiconductor device according to claim 18, wherein
the outer enclosure of the semiconductor module is molded with an encapsulating member, and
the spacer member is made of the same material as the encapsulating member.

20. The semiconductor device according to claim 11, wherein
the cooling module is made of metal and includes a heat dissipation plate, a surface of the heat dissipation plate being the placement surface of the cooling module, and
the spacer member is made of a same material as the heat dissipation plate and is integrally formed with the placement surface of the cooling module.
